(19) United States
(12) Patent Application Publication
(10) Pub. No.: US 2024/0013966 A1
(43) Pub. Date: Jan. 11, 2024

(54) INTEGRATED MAGNETIC DEVICE AND FILTER CIRCUIT

(71) Applicant: Telefonaktiebolaget LM Ericsson (publ), Stockholm (SE)

(72) Inventors: Chong ZHAO, Beijing (CN); Jiashen TIAN, Beijing (CN); Jianping ZHENG, Beijing (CN); Tianyu LIN, Beijing (CN)

(21) Appl. No.: 18/250,399

(22) PCT Filed: Nov. 2, 2020
(86) PCT No.: PCT/CN2020/125888

§ 371 Date: Apr. 25, 2023

(51) Int. Cl. H01F 27/28; H01F 17/04; H01F 27/26; H01F 27/255

(52) U.S. Cl. CPC H01F 27/28; H01F 17/04; H01F 27/263; H01F 27/255

(57) ABSTRACT

An integrated magnetic component has a common magnetic core portion having a first magnetic base and a second magnetic base that is spaced in a first direction from the first magnetic base; a first magnetic core column and a second magnetic core column, which extend between the first and second magnetic bases and spaced with each other along a second direction perpendicular to the first direction. The first magnetic core column and the second magnetic core column and the first and second magnetic bases form a closed magnetic path. The first magnetic core column and the second magnetic core column have windings forming one or more common mode chokes. A middle magnetic core portion has an air gap being provided in an extension direction of the middle magnetic core portion which is made of high saturation magnetic material, and has a winding forming a decoupling inductor.

### TECHNICAL FIELD

The present disclosure generally relates to the technical field of an inductor device, and more particularly, to an integrated magnetic device and a filter circuit comprising the integrated magnetic device.

### BACKGROUND

This section introduces aspects that may facilitate better understanding of the present disclosure. Accordingly, the statements of this section are to be read in this light and are not to be understood as admissions about what is in the prior art or what is not in the prior art.

A surge protection device (SPD) is an electrical device installed on power lines or communication lines to protect electrical equipment/loads from lightning pulses or overvoltage damage. FIG. 15 shows a schematic diagram of the circuit layout of a conventional SPD in a power line or a communication line. As shown in FIG. 15, the SPD comprises a surge arrester 201 connected parallel with a 0V transmission line and the ground line, a stacked surge arrester 202 connected parallel with a −48V transmission line and the ground line, a decoupling inductor 203 (also called “SPD inductor”) connected in series with the −48V transmission line and positioned downstream of the surge arrester, and metal-oxide varistors (MOVs) 204 connected parallel with the 0V transmission line and the −48V transmission line and positioned downstream of the decoupling inductor. Especially, in a radio product, the SPD inductor can function to impede lightning current and urge the current to go to the surge arrester and the stacked surge arrester and further, to the ground.

For blocking high frequency noise common on two or more data or power lines while allowing the desired direct current (DC) or low-frequency signal to pass, a common mode choke 205 is arranged downstream of the MOV. The Common mode choke is an important component, especially, in an EMI/EMC filter. Most of common mode chokes consist of a toroid core with two or more windings. For example, the common mode choke comprises two windings each connected in series in the ground line and the −48V transmission line. In a common mode, the current in the windings travels in the same direction so that the combined magnetic flux adds to create large impedance to block the noise. In a differential mode, the current travels in opposite directions and the magnetic flux generated subtracts or cancels out so that no impedance is created to suppress the normal mode signal.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

One of the objects of the disclosure is to provide an integrated magnetic device fulfilling both the SPD function and the EMC filtering function, with a compact structure and reduced manufacturing cost.

According to a first aspect of the disclosure, there is provided an integrated magnetic (IM) device, comprising: a common magnetic core portion comprising a first magnetic base and a second magnetic base that is spaced in a first direction from the first magnetic base; a first magnetic core column and a second magnetic core column, which extend between the first and second magnetic bases and spaced with each other along a second direction perpendicular to the first direction, the first magnetic core column and the second magnetic core column and the first and second magnetic bases together forming a closed magnetic path, and the first magnetic core column and the second magnetic core column having windings wound thereon so as to form one or more common mode chokes; and a middle magnetic core portion extending between the first and second magnetic bases and located between the first magnetic core column and the second magnetic core column along the second direction, with an air gap being provided in an extension direction of the middle magnetic core portion which is made of high saturation magnetic material, and the middle magnetic core portion comprising a winding wound thereon so as to form a decoupling inductor.

In an embodiment of the disclosure, the middle magnetic core portion is in the form of a single column, with the air gap being formed between an end of the single column and an inner side of a magnetic base which the single column extends towards.

In an embodiment of the disclosure, the first magnetic core column and the second magnetic core column and the common magnetic core portion are made of the same magnetic material with high permeability.

In an embodiment of the disclosure, the first magnetic core column and/or the second magnetic core column are integrally formed with the first magnetic base and/or the second magnetic base of the common magnetic core portion.

In an embodiment of the disclosure, the first magnetic core column and/or the second magnetic core column are formed by two abutting halves protruding from one of the magnetic bases towards the other.

In an embodiment of the disclosure, the halves of the first magnetic core column and/or the second magnetic core column are integrally formed with magnetic bases of the common magnetic core portion.

In an embodiment of the disclosure, a first winding and a third winding are provided on the first magnetic core column and arranged next to each other along the first direction, with the first winding being placed adjacent to the first magnetic base. A second winding and a fourth winding are provided on the second magnetic core column and arranged next to each other along the first direction, with the second winding being placed adjacent to the first magnetic base. A fifth winding is provided on the middle magnetic core portion. Each winding has a first end and a second end which is located closer to the first magnetic base than the first end.

In an embodiment of the disclosure, the first winding, the second winding, the third winding and the fourth winding are wound and connected in such a manner that a first common mode choke is formed by the first winding and the third winding, and a second common mode choke is formed by the second winding and the fourth winding.

In an embodiment of the disclosure, the first winding, the second winding, the third winding, the fourth winding and the fifth winding each have coils wound in the same direction. And a second end of the fifth winding is connected to a second end of the first winding, a first end of the first winding is connected to a first end of the second winding. A second end of the third winding is connected to a second end of the fourth winding. And a second end of the second winding, a first end of the third winding, a first end of the fourth winding and a first end of the fifth winding are all led out as peripheral interfaces of the integrated magnetic device.

In an embodiment of the disclosure, the first winding, the second winding, the third winding and the fourth winding are wound and connected in such a manner that a first common mode choke is formed by the first winding and the second winding and a second common mode choke is formed by the third winding and the fourth winding.

In an embodiment of the disclosure, the first winding, the second winding, the third winding and the fourth winding each have coils wound in the same direction. And a second end of the fifth winding is connected to a second end of the first winding, a first end of the first winding is connected to a second end of the third winding. A first end of the second winding is connected to a second end of the fourth winding. And a second end of the second winding, a first end of the third winding, a first end of the fourth winding and a first end of the fifth winding are all led out as peripheral interfaces of the integrated magnetic device.

In an embodiment of the disclosure, the fifth winding has coils wound in the same direction as coils of the first winding, the second winding, the third winding and the fourth winding, such that magnetic flux produced by the fifth winding on the middle magnetic core portion and leakage flux generated by the first, second, third and fourth windings are superimposed with each other.

In an embodiment of the disclosure, the fifth winding has coils wound in an opposite direction to coils of the first winding, the second winding, the third winding and the fourth winding, such that magnetic flux produced by the fifth winding on the middle magnetic core portion and leakage flux generated by the first, second, third and fourth windings are canceled with each other.

In an embodiment of the disclosure, the magnetic material with high permeability comprises Mn—Zn soft ferrite material.

In an embodiment of the disclosure, the high saturation magnetic material comprises powder core.

In an embodiment of the disclosure, the integrated magnetic device comprises a side support plate connecting the first and second magnetic bases along their longitudinal edges on the same side.

In an embodiment of the disclosure, the side support plate is made of epoxy material.

In an embodiment of the disclosure, the integrated magnetic device comprises a support frame arranged at a side opposite to the side where the side support plate is located, the support frame being configured for fixing pins led out from windings wound on the first and second magnetic core columns and the middle magnetic core portion.

In an embodiment of the disclosure, the support frame is made of phenolic plastics.

According to a second aspect of the disclosure, there is provided a filter circuit, comprising a first transmission line, a second transmission line and an integrated magnetic device as indicated in the above, wherein each of the one or more common mode chokes comprises a winding connected in series in the first transmission line and a winding connected in series in the second transmission line, the decoupling inductor of the integrated magnetic device is connected in series in the second transmission line, with the winding of each common mode choke in the second transmission line being connected in series downstream of the decoupling inductor.

According to the present disclosure, the SPD decoupling inductor and EMC's common mode choke share the same magnetic core frame, allowing integration of an SPD's function and an EMC filtering function into one single physical unit. By proper phasing of the windings and the placement of an air gap in a specific location in the flux path, magnetic integration allows more efficient use of the cross-sectional area of the inductor core, resulting in a reduced need for core material. Two magnetic components share one core and the flux trajectory benefits each other. High common mode inductance and high leakage inductance can be obtained depending on the practical needs, and also high decoupling inductor's inductance can be ensured. This integrated magnetic device of the present disclosure can provide both improved lightning/surge protection and improved EMC/EMI filtering performance. Its DC resistance is reduced, saving much more energy.

In addition, the integrated magnetic device of the present disclosure could allow reducing the space occupied by more than 54% and saving weight by 61%. The height of new component is lower than current designs, which shows a great potential in minimizing our product in future. Because during the manufacturing process, only one single integrated component is subject to soldering, and thus the risk of cold soldering may be avoided or reduced to its minimum. The management and logistic supply chain of components will become simple. And the integrated magnetic device can save more than 50% in terms of manufacturing cost.

The integrated magnetic device of the present disclosure has a unique appearance and an impact structure and thus is easy to distinguish from the current designs for an SPD inductor or common mode chokes.

### BRIEF DESCRIPTION OF THE DRAWINGS

These and other objects, features and advantages of the disclosure will become apparent from the following detailed description of illustrative embodiments thereof, which are to be read in connection with the accompanying drawings.

FIG. 1 shows a perspective view of the integrated magnetic device according to the present disclosure, in which the support frame is omitted for the sake of clarity;

FIG. 2 shows a bottom view of the integrated magnetic device of FIG. 1;

FIG. 3 shows a perspective view of the integrated magnetic device according to the present disclosure without windings wound therein;

FIG. 4 shows a part of the integrated magnetic device according to the present disclosure before assembling;

FIG. 5 shows a perspective view of a support frame of the integrated magnetic device according to the present disclosure;

FIG. 6 shows the wiring layout in a first application of the integrated magnetic device according to the present disclosure;

FIG. 7 shows the filter circuit in which the integrated magnetic device of FIG. 6 is used to achieve both the lighting protection and the EMC filtering function;

FIG. 8 shows change in the common mode leakage inductance generated by the integrated magnetic device of FIG. 6, as a function of the current therethrough;

FIG. 9 shows change in the sum of the common mode leakage and the SPD inductance generated by the integrated magnetic device of FIG. 6, as a function of the current therethrough;

FIG. 10 shows the wiring layout in a second application of the integrated magnetic device according to the present disclosure;

FIG. 11 shows the filter circuit in which the integrated magnetic device of FIG. 10 is used to achieve both the lighting protection and the EMC filtering function;

FIG. 12 shows change in the common mode leakage inductance generated by the integrated magnetic device of FIG. 10, as a function of the current therethrough;

FIG. 13 shows change in the sum of the decoupling inductance and the common mode leakage inductance generated by the integrated magnetic device of FIG. 10, as a function of the current therethrough;

FIG. 14 shows the DC-bias curve (change in the sum of the decoupling inductance and the common mode leakage inductance generated as a function of the current therethrough) of an integrated magnetic device which is substantially the same as that shown in FIG. 10 with an exception that the decoupling inductor has a winding wound in a direction different from that of the integrated magnetic device of FIG. 10; and

FIG. 15 shows a portion of a conventional filter circuit comprising an SPD inductor and a common mode choke which are provided separately.

### DETAILED DESCRIPTION

The embodiments of the present disclosure are described in detail with reference to the accompanying drawings. It should be understood that these embodiments are discussed only for the purpose of enabling those skilled in the art to better understand and thus implement the present disclosure, rather than suggesting any limitations on the scope of the present disclosure. Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Furthermore, the described features, advantages, and characteristics of the disclosure may be combined in any suitable manner in one or more embodiments. Those skilled in the relevant art will recognize that the disclosure may be practiced without one or more of the specific features or advantages of a particular embodiment. In other instances, additional features and advantages may be recognized in certain embodiments that may not be present in all embodiments of the disclosure.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

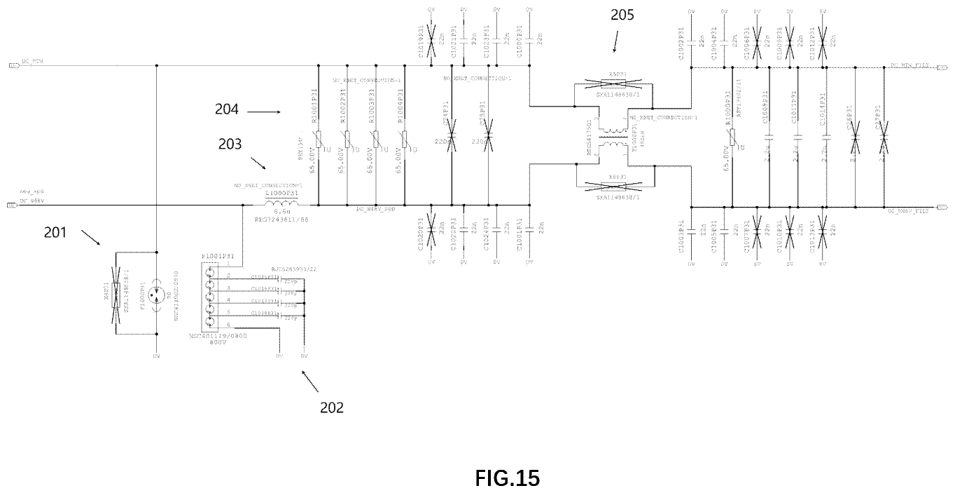

In most cases, for achieving better performance, two common mode chokes can be adopted in a conventional filter circuit as shown in FIG. 15. The two common mode chokes are usually connected almost together and installed in the edge of a radio board. The cold soldering always happens to the common mode chokes, especially because they have a big volume and most of the heat provided for soldering is absorbed by magnetic cores of the common mode chokes.

As for the conventional filter circuit, the decoupling inductor used in a radio product is often huge (its volume may be up to 14062.5 mm³). A common mode choke may have a volume of up to 13900.05 mm³. These two components thus occupy a lot of space on the printed circuit board (PCB). Cold soldering problem happens easily in manufacturing because of their big volume. Also, the SPD inductor and the common mode choke are quite expensive. Additionally, the power density of the two components is low.

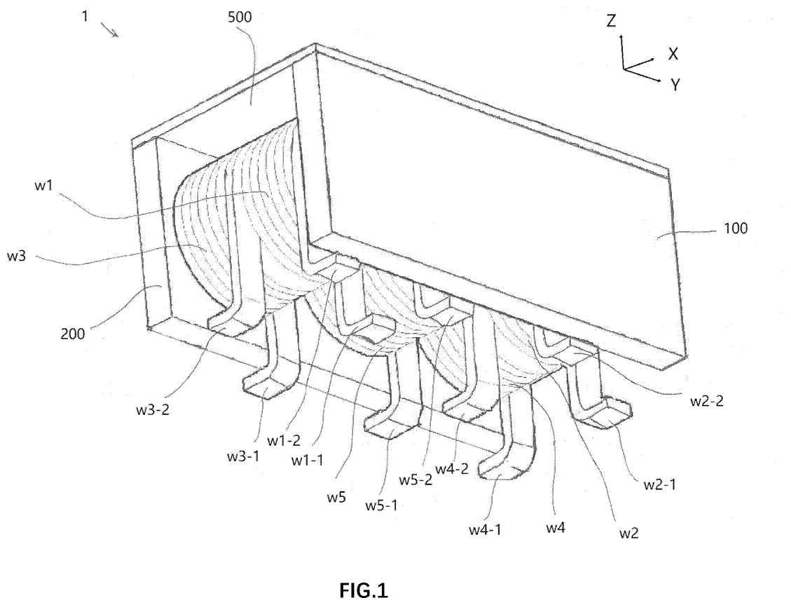

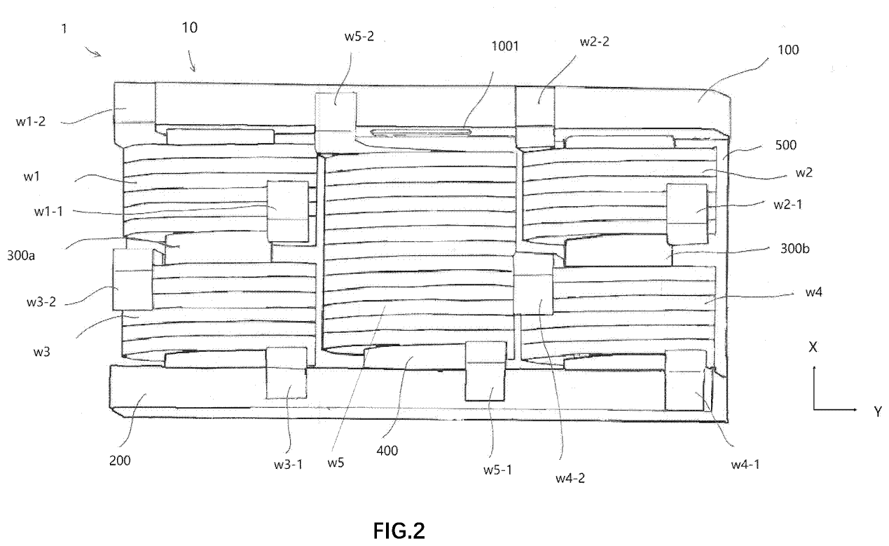

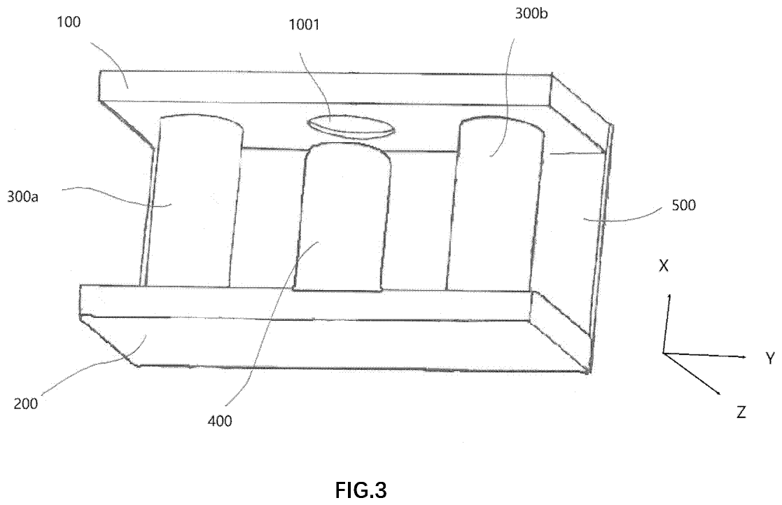

FIGS. 1 and 2 show different views of a main part of the integrated magnetic device 1 according to the present disclosure. FIG. 3 shows the basic core arrangement of the integrated magnetic device of the present disclosure, without windings thereon. The integrated magnetic device 1 comprises a first magnetic base 100 and a second magnetic base 200. The first magnetic base 100 and the second magnetic base 200 are spaced from each other in an X direction as shown in FIGS. 1-3. In the embodiment shown in FIG. 1, the first magnetic base and the second magnetic base are substantially plate-shaped. A first magnetic core column 300a and a second magnetic core column 300b extend between the first and second magnetic bases and are spaced with each other along a Y direction, as shown in FIG. 2. The first magnetic core column 300a and the second magnetic core column 300b and the first and second magnetic bases together define or form a closed magnetic path (or a closed-loop path for magnetic flux). In an embodiment of the present disclosure, the first magnetic core column and the second magnetic core column and the first and second magnetic bases are made of the same magnetic material with high permeability, for example, Mn—Zn soft ferrite material. The first magnetic core column and/or the second magnetic core column may be integrally formed with the first and/or second magnetic base(s).

Hereinbelow, the term “magnetic material with high permeability” refers to ferromagnetic materials with magnetic permeability above 100, preferably above 5000, more preferably above 10000.

The integrated magnetic device 1 further comprises a middle magnetic core portion 400 extending between the first magnetic base 100 and the second magnetic base 200 and located between the first magnetic core column 300a and the second magnetic core column 300b along the Y direction. An air gap is provided in an extension direction of the middle magnetic core portion 400. The middle magnetic core portion is made of a high saturation magnetic material, for example, iron powder core. Herein, the term “high saturation magnetic material” refers to a magnetic material with the saturation magnetic induction Bs≥1.2T, preferably Bs≥1.7.

In the embodiment shown in FIGS. 1-3, the middle magnetic core portion 400 is in the form of a single column protruding from the second magnetic base 200 towards the first magnetic base 100. The air gap is located between an end of the single column and an inner side of the first magnetic base, so as to create a large magnetic resistance at the air gap. The air gap can be adjusted so as to change the DC-bias performance associated with the middle magnetic core portion. Also, it can be easily conceived by the skilled in the art that the middle magnetic core portion can be designed differently, for example, comprising two column sections coaxially protruding from the first and second magnetic bases respectively and having their ends spaced with each other so as to form the air gap therebetween.

As can be seen from FIG. 2, the first magnetic core column 300a and the second magnetic core column 300b have windings wound thereon respectively. The windings on the first and second magnetic core columns are matched in such a manner that one or more common mode chokes are created thereby. In the embodiment shown in FIG. 2, there are two sets of windings, namely, a first winding w1 and a third winding w3, wound on the first magnetic core column 300a and two sets of windings, namely a second winding w2 and a fourth winding w4, wound on the second magnetic core column 300b. Although it is shown that there are two windings on the first/second magnetic core column, it can be readily envisaged that the number of windings on the first magnetic core column or the second magnetic core column can be set differently according to practical needs. Also, although it is shown that each winding has 6 turns of coils, the skilled in the art could easily envisage that the number of turns for each winding can be changed according to specific applications.

As can be seen from FIGS. 1 and 2, the middle magnetic core portion 400 has a winding wound thereon so that it can function as a decoupling inductor for surge protection. For better illustration, the winding wound on the middle magnetic core portion is referred to as “a fifth winding w5” hereinafter.

Sections of the magnetic path defined by the first magnetic base 100 and the second magnetic base 200 are shared by the windings w1, w2, w3, w4 on the first magnetic core column 300a and the second magnetic core column 300b and the winding w5 on the middle magnetic core portion 400 as well. Therefore, the first and second magnetic bases 100, 200 constitute a common magnetic core portion 10 for both the common mode choke(s) and the decoupling inductor. The arrangement of the common magnetic core portion 10 also makes it possible to integrate the common mode choke(s) and the decoupling inductor into one magnetic core unit in which the common mode choke(s) and the decoupling inductor benefit each other in terms of the inductance generated. Therefore, the integrated magnetic device of the present disclosure can not only fulfill the function of surge protection, but also achieve the EMC/EMI filtering function, on its own.

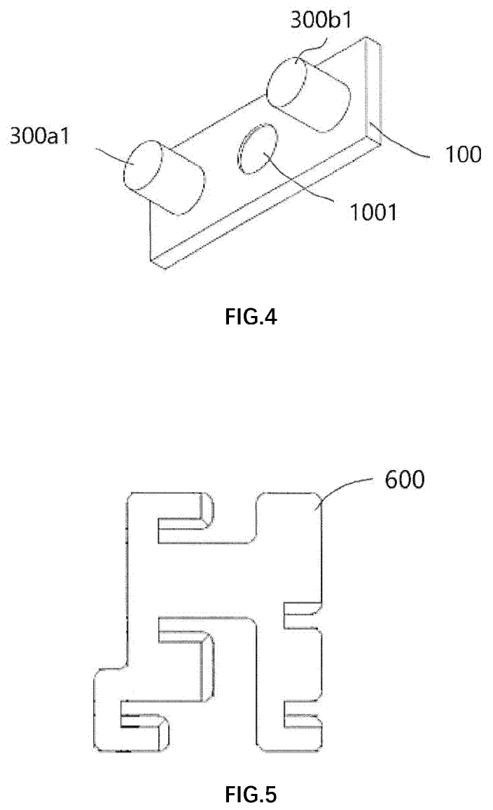

From FIG. 3, it can be seen that the first magnetic core column 300a and/or the second magnetic core column 300b may be made separately with respect to the first magnetic base 100 or the second magnetic base 200, and then attached to the magnetic bases, for example, by adhesives. In a preferable embodiment, the first magnetic core column 300a and/or the second magnetic core column 300b can be formed by two abutting segments each integrally formed with the first and second magnetic bases. In the embodiment shown in FIG. 4, the first magnetic core column 300a and the second magnetic core column 300b each consist of one segment 300a1, 300b1 (for example, one half) integrally formed on the first magnetic base and the other segment (for example, the other half) integrally formed on the second magnetic base. During assembling, the first magnetic base with segments of the first and second magnetic core columns is attached to the second magnetic base with the other segments of the first and second magnetic core columns, such that corresponding segments of the first and second magnetic core column are aligned coaxially and joined to each other with adhesives applied on corresponding abutting ends of the segments. In this case, windings may need to be wound on corresponding segments before abutting the segments with each other to form corresponding inductors with the first magnetic column and the second magnetic column.

As can be seen from FIG. 4, a positioning recess 1001 is provided on the first magnetic base 100, facing the middle magnetic core portion 400 protruding from the second magnetic base 200. Similarly, a positioning recess may be provided on the second magnetic base for engaging with the end of the middle magnetic core portion. The positioning recess on the first magnetic base and the positioning recess on the second magnetic base are actually aligned to each other in the X direction when the integrated magnetic device is well assembled. Therefore, these positioning recesses can help to position the middle magnetic core portion 400 and to adjust the air gap between the free end of the middle magnetic core portion and the inner side of the magnetic base which the middle magnetic core portion protrudes towards. Also, the first and second magnetic base can be made identical to each other so that there is no need to distinguish the first magnetic base from the second magnetic base, especially when they both have halves of the first and second magnetic core columns integrally formed on the side where the positioning recesses are located. In this case, the middle magnetic core portion can be formed by two protrusions which are integrally formed with the first magnetic base and the second magnetic base respectively and spaced from each other in the X direction by an air gap in the area of their free ends.

Referring to FIGS. 1-3, it can be seen that a side support plate 500 is provided connecting the first and second magnetic bases along their longitudinal edges on the same side, and extending substantially in the XY-plane. The side support plate 500 is made of epoxy material. By means of suction on the side support plate, the whole integrated magnetic device can be caught and moved to a predetermined position on a printed circuit board in which it can be electrically connected in a way as desired.

The integrated magnetic device 1 comprises at least one support frame 600 arranged on a side opposite to the side where the side support plate is located. The support frame 600 is configured for fixing pins led out from windings wound on the first and second magnetic core columns 300a, 300b and the middle magnetic core portion 400 (as shown in FIGS. 5, 6 and 10). The support frame may be made of phenolic plastics.

Hereinbelow, the working principle of the integrated magnetic device of the present disclosure and its applications will be explained in detail as follows:

For the sake of better illustration, terms “upper” or “lower” and “above” or “below” are used here to explain the arrangement of the windings. And the up-down direction is referred to be coincident with the X direction shown in FIG. 2. Referring back to FIG. 2, the first winding w1 is placed above the third winding w3, and the second winding w2 is placed above the fourth winding w4. The middle magnetic core portion 400 protrudes along the X direction from the second magnetic base 200 towards the first magnetic base 100. All the windings are wound on corresponding magnetic cores in the same direction. For example, the coils of all the windings are wound in a counterclockwise direction. Each winding has a winding starting end (i.e. a first end) and a winding finishing end (i.e. a second end). All the windings are arranged in such a manner that the winding finishing end is placed above the winding starting end.

For the sake of simplicity, the following mainly focuses on the hardware connection of critical components closely related to the present disclosure, such as SPD inductors and common mode chokes, while omitting connections on various additional components in the peripheral circuit, for example, filter capacitors, MOVs. Those skilled in the art can easily understand that, to ensure proper function of the SPD inductor and the common mode chokes, corresponding peripheral circuit is indispensable, which can be chosen easily from conventional selections.

The First Scenario

Connections and Operating Mechanism of the Integrated Magnetic Device

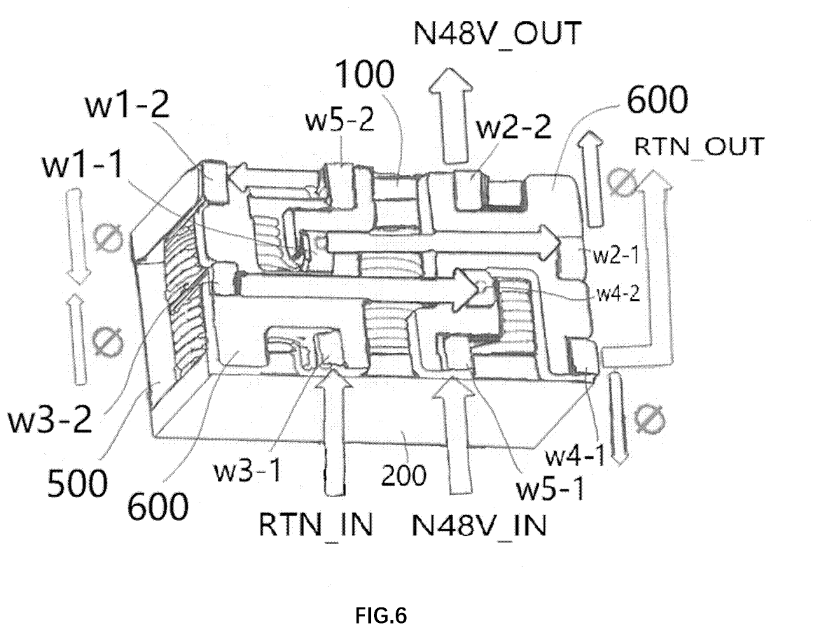

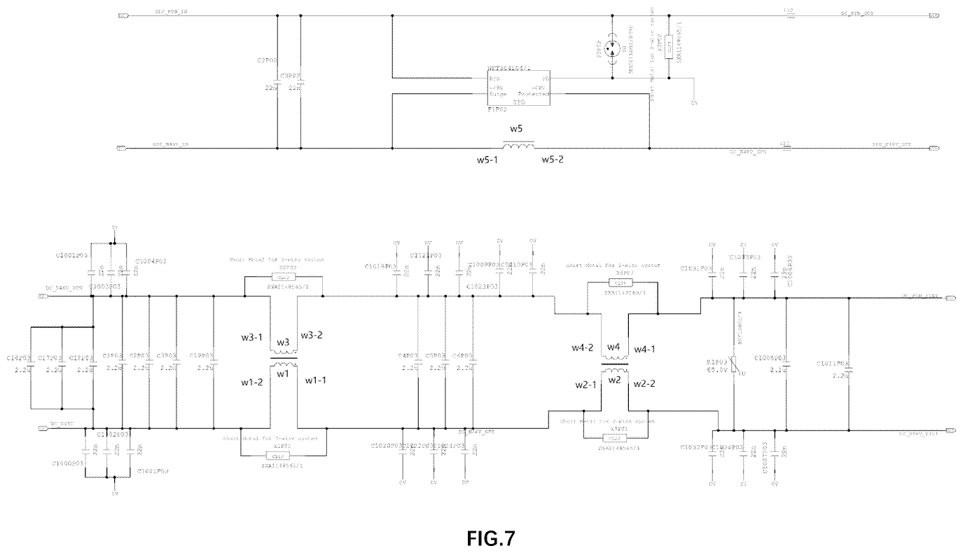

As can be seen from FIG. 6, the second end w5-2 of the fifth winding w5 is connected to the second end w1-2 of the first winding w1, the first end w1-1 of the first winding w1 is connected to the first end w2-1 of the second winding w2, and the second end w3-2 of the third winding w3 is connected to the second end w4-2 of the fourth winding w4. The second end w2-2 of the second winding w2, the first end w3-1 of the third winding w3, the first end w4-1 of the fourth winding w4, and the first end w5-1 of the fifth winding w5 respectively constitute the four external interfaces/pins of the integrated magnetic device (connected to the terminals N48V_IN, N48V_OUT, RTN_IN, RTN_OUT of transmission lines, for example, 0 V line (RTN line) and −48V line (N48V_line) shown in FIG. 7). In this scenario, the first winding w1 and the third winding w3 are matched to form a first common mode choke, and the second winding w2 and the fourth winding w4 are matched to form a second common mode choke.

In the actual circuit as shown in FIG. 7, the fifth winding w5 is connected in series on the −48V power line, and the first and second windings w1, w2 are connected in series downstream of the fifth winding w5. In addition, the third and fourth windings w3, w4 are connected in series on the RTN line.

Specifically, the first end w5-1 of the fifth winding w5 is connected to the input terminal N48V_IN of the −48V power line, the second end w2-2 of the second winding w2 is connected to the output terminal N48V_OUT of the −48V power line, and the first end w3-1 of the third winding w3 is connected to the input terminal RTN_IN of the RTN line and the first end w4-1 of the fourth winding w4 is connected to the output terminal RTN_OUT of the RTN line.

When the circuit is in a normal working state, on the −48V transmission line, the current flows into the integrated magnetic device through the first end w5-1 of the fifth winding w5, and then passes through the first winding w1 and the second winding w2, finally flows out through the second end w2-2 of the second winding w2; on the RTN line, the current flows through the first end w3-1 of the third winding w3 into the integrated magnetic device and flows out through the first end w4-1 of the fourth winding w4. At this time, the normal working current generates a reverse magnetic field in the two coils wound in the same direction in each common mode choke. As shown in FIG. 6, the first winding w1 in the first common mode choke generates a downward magnetic field in the first magnetic core column 300a. The third winding w3 in the first common mode choke generates an upward magnetic field in the first magnetic core column 300a, and the two cancel each other out, and will not inhibit the normal working current; similarly, the second winding w2 in the second common mode choke generates an upward magnetic field in the second magnetic core column 300b, and the fourth winding w4 in the second common mode choke generates a downward magnetic field in the second magnetic core column 300b, and the two cancel each other out, and will not inhibit the normal working current either.

When common-mode interference occurs in the transmission lines, the common-mode interference will generate a magnetic field in the same direction in the two windings of each set of common-mode choke. The two magnetic fields generated are superimposed on each other to increase the inductive reactance of the windings and make the windings exhibit high impedance, which therefore has a strong damping effect on common mode interference. For example, in the first common mode choke, the first winding w1 and the third winding w3 both generate upward magnetic fields, which are superimposed on each other to form a strong inductance on the first magnetic core column 300a; similarly, in the second common mode choke, the second winding w2 and the fourth winding w4 both generate downward magnetic fields, and the two magnetic fields generated are superimposed on each other to form a strong induction inductance on the second magnetic core column 300b. In addition, because the two sets of common mode chokes share a single integrated magnetic core, the inductances formed by the two are further superimposed on the common magnetic path, which can effectively suppress common mode interference and achieve the purpose of filtering.

Reaction Between the Leakage Inductance and the SPD Inductance in the First Scenario

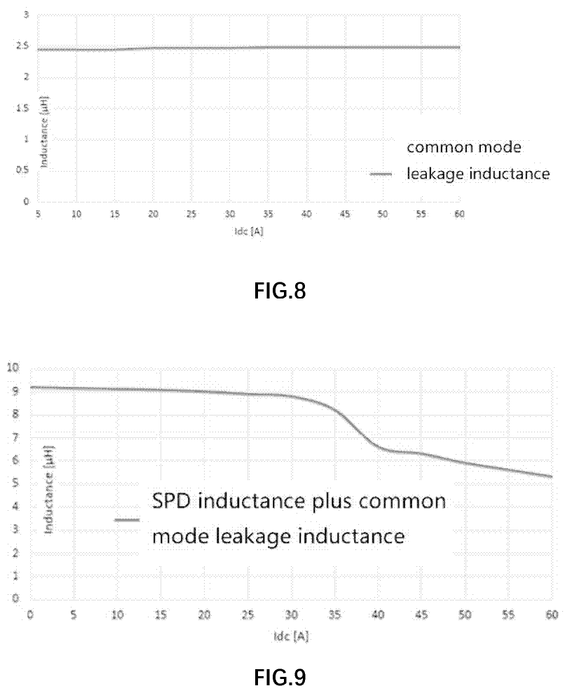

In this scenario, the normal working current in the circuit is only affected by a small amount of common-mode leakage inductance generated by the common-mode chokes, in view of that the two windings (for example, the first winding w1 and the third winding w3) on the same magnetic core column can be coupled well, and the leakage fluxes generated are opposite to each other and most of them cancel each other out on the same magnetic core column. Therefore, the overall leakage inductance in this scenario is small, usually around 2.5 μH, as shown in FIG. 8. This part of the leakage inductance can be used to eliminate differential mode noise.

In addition, the middle magnetic core portion 400 is made of a high saturation material, which can withstand a higher bias current. When large lightning current flows through the circuit, the SPD inductor will not easily enter into a magnetic saturation state and can thus generate sufficient induction inductance to suppress the passing of lightning current. In the existing SPD inductor provided separately, the decoupling inductance generated is about 6.5 μH. While in this embodiment of the present disclosure, due to the use of an integrated magnetic core structure, the leakage inductance generated by the common mode chokes will be superimposed on the SPD inductor, thereby increasing the inductive effect of the SPD inductor, as shown in FIG. 9. The inductance after superimposition can reach about 9 μH, and because the inductance is less affected by the change of the bias current, the configuration of the integrated magnetic device according to this embodiment is suitable for scenarios with small differential mode signal and large bias current.

Although it is shown in FIG. 6 that the current in the −48v transmission line flows into the IM device from the first end w5-1 of the fifth winding w5 and out from the second end w2-2 of the second winding w2, while the current in the RTN line enters into the IM device from the first end w3-1 of the third winding w3 and out from the first end w4-1 of the fourth winding w4, it can be easily conceived that the direction of the current on the path consisting of the fifth winding w5, the first winding w1 and the second winding w2 and/or that of the current on the path consisting of the third winding w3 and the fourth winding w4 can be changed as required in practical application. For example, the direction of the current on these two paths can be reversed by adopting the second end w2-2 of the second winding w2 and the first end w4-1 of the fourth winding w4 as input terminals and the first end w5-1 of the fifth winding w5 and the first end w3-1 of the third winding w3 as output terminals. With this change in current direction, the integrated magnetic device of the present disclosure can still function in the same way as that of FIG. 6 and thus be still applicable to the first scenario.

The Second Scenario

Connections and Operating Mechanism of the Integrated Magnetic Device

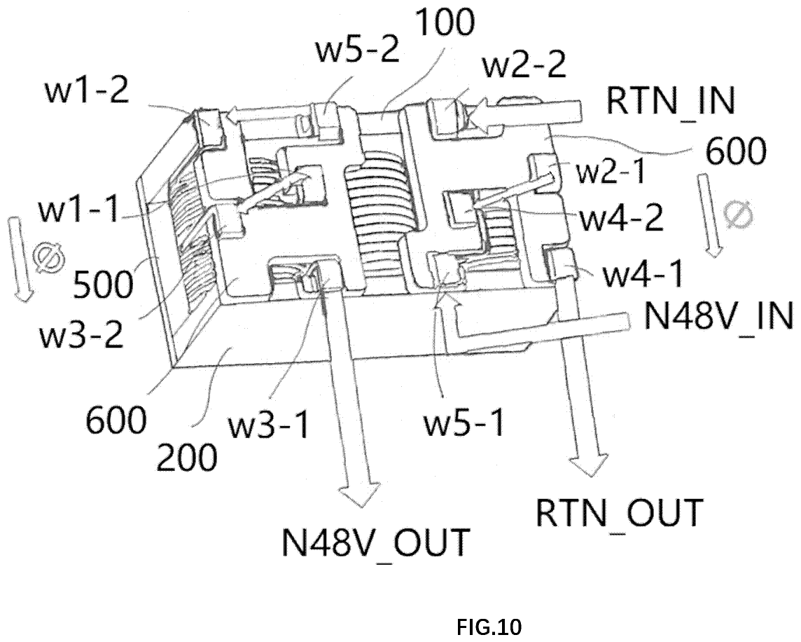

As can be seen from FIG. 10, the second end w5-2 of the fifth winding w5 is connected to the second end w1-2 of the first winding w1, the first end w1-1 of the first winding w1 is connected to the second end w3-2 of the third winding w3, and the first end w2-1 of the second winding w2 is connected to the second end w4-2 of the fourth winding w4. The second end w2-2 of the second winding w2, the first end w3-1 of the third winding w3, the first end w4-1 of the fourth winding w4, and the first end w5-1 of the fifth winding w5 respectively constitute four external interfaces/pins of the integrated magnetic device. In this scenario, the first winding w1 and the second winding w2 are matched to form a first common mode choke, and the third winding w3 and the fourth winding w4 are matched to form a second common mode choke.

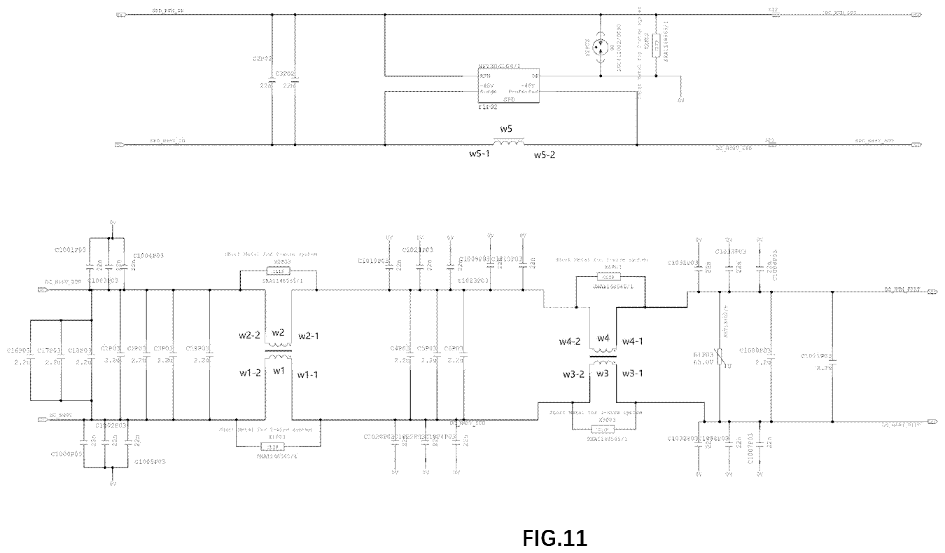

In the circuit as shown in FIG. 11, the fifth winding w5 is connected in series on the −48V transmission line, and the first and third windings w1, w3 are connected in series downstream of the fifth winding w5. In addition, the second winding w2 and the fourth winding w4 are connected in series on the RTN line.

When the circuit is in a normal operating state, on the −48V transmission line, the current flows into the integrated magnetic device through the first end w5-1 of the fifth winding w5, and then passes through the first winding w1 and the third winding w3, finally flows out through the first end w3-1 of the third winding w3; on the RTN line, the current flows through the second end w2-2 of the second winding w2 into the integrated magnetic device and flows out through the first end w4-1 of the fourth winding w4. At this time, the first and third windings w1, w3 wound on the first magnetic core column 300a can be combined into one single winding (a first combined winding), and the second and fourth windings w2, w4 wound on the second magnetic core column 300b can be combined into another single winding (i.e. a second combined winding). Two combined windings can actually form a combined common mode choke, and the normal working current produces opposite magnetic fields in these two combined windings. As shown in FIG. 10, these two magnetic fields cancel each other out in the magnetic circuit and will not inhibit the normal working current.

When common mode interference occurs in the transmission line, the common mode interference will generate the same magnetic field in the two combined windings of the combined common mode choke. They are superimposed on each other in the magnetic path to increase the inductive reactance of the windings and make the windings obtain high impedance, thereby producing a strong damping effect on common mode interference and achieving the purpose of filtering.

Reaction Between the Leakage Inductance and the SPD Inductance in the Second Scenario

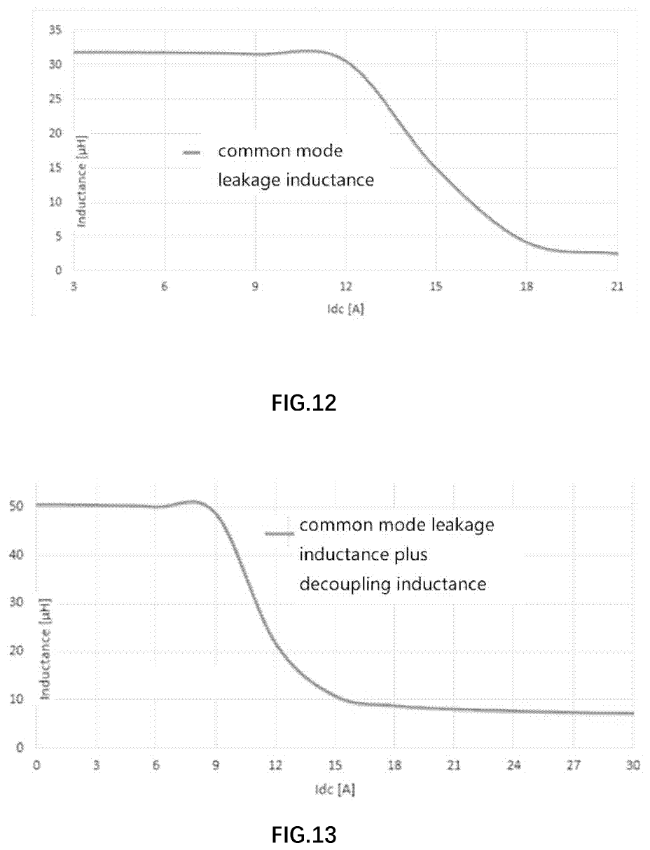

In this scenario, the normal working current in the circuit is only affected by the common mode leakage inductance generated by the combined common mode choke, because the inductance generated by the two windings (for example, the first winding w1 and the third winding w3) on the same magnetic core column must go through a long magnetic path to be coupled with the inductance generated by the other two windings (for example, the second winding w2 and the fourth winding w4) on the other magnetic core column. Therefore, the overall leakage inductance of the integrated magnetic device is relatively large in this scenario. Under a testing condition with 0.1V and 100 kHz, common mode leakage inductance is around 31.5 μH, as shown in FIG. 12. This part of the leakage inductance can be used to eliminate differential mode noise. However, as the bias current increases, both the first and second magnetic core columns will enter into a magnetic saturation state, resulting in the inductance generated by the first, second, third and fourth windings w1-w4 dropping sharply, for example, at a bias current of about 15A, and therefore rendering a poor induction effect. Hence, this configuration as shown in FIG. 10 is suitable for scenarios with large differential mode signals and low bias current.

In addition, due to the use of an integrated magnetic core structure, a part of the leakage inductance generated by the combined common mode choke will interact with the SPD inductance via the middle magnetic core portion. Specifically, depending on whether the winding direction of the fifth winding w5 on the middle magnetic core portion and the winding direction of the four windings w1-w4 on the first and second magnetic core columns on the left-right sides are same or different, the SPD inductance and the leakage inductance generated by the four windings w1-w4 may be cancelled out or superimposed with each other.

Magnetic Path Superimposition Mode

When the winding direction of the fifth winding w5 is the same as that of the four windings w1-w4, the leakage inductance and the SPD inductance will be superimposed on each other. As shown in FIG. 13, the superimposed inductance can reach about 50.5 μH. However, in this magnetic path superimposition mode, the inductance is greatly affected by the change of the bias current. When the bias current reaches about 15A, the inductance generated will drop sharply. Therefore, this magnetic path superposition mode is not suitable for scenarios with high bias current.

Magnetic Path Cancellation Mode

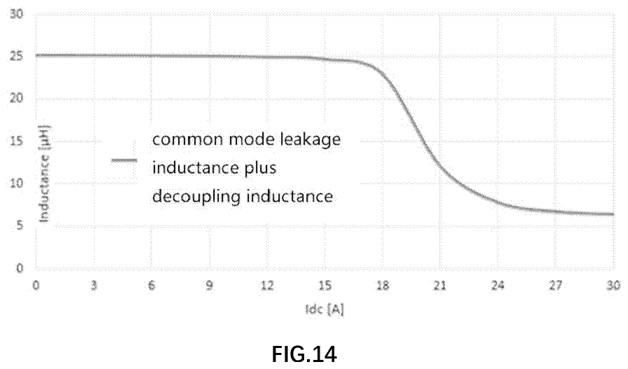

When the winding direction of the fifth winding w5 is opposite to that of the four windings w1-w4, the leakage inductance and the SPD inductance will cancel out with each other. As shown in FIG. 14, the inductance after cancellation is about 25.2 μH. Compared with the magnetic path superimposition mode, the inductance in this magnetic path cancellation mode is relatively less affected by the change of the bias current. The inductance begins to drop when the bias current reaches about 18A. Therefore, as compared with the magnetic path superimposition mode, the magnetic path cancellation mode is more tolerant to high bias current.

Although it is shown in FIG. 10 that the current in the −48v transmission line flows into the IM device from the first end w5-1 of the fifth winding w5 and out from the first end w3-1 of the third winding w3, while the current in the RTN line enters into the IM device from the second end w2-2 of the second winding w2 and out from the first end w4-1 of the fourth winding w4, it can be easily conceived that the direction of the current on the path consisting of the fifth winding w5, the first winding w1 and the third winding w3 and/or that of the current on the path consisting of the second winding w2 and the fourth winding w4 can be changed as required in practical application. For example, the direction of the current on these two paths can be reversed by adopting the first end w3-1 of the third winding w3 and the first end w4-1 of the fourth winding w4 as input terminals and the first end w5-1 of the fifth winding w5 and the second end w2-2 of the second winding w2 as output terminals. With this change in current direction, the integrated magnetic device of the present disclosure can still function in the same way as that of FIG. 10 and thus be still applicable to the second scenario.

As stated in the above, the integrated magnetic device of the present disclosure may be applicable to different application scenarios, by changing the winding direction of the windings, the current direction flowing through the windings, and the connections among the windings. It can be readily understood that the specific configurations (including the arrangement of the windings, their connections and the current directions therethrough) of the integrated magnetic device shown in FIGS. 6 and 10 are shown only as examples for the first and second application scenarios, and should not be interpreted as limitative for the integrated magnetic device of the present disclosure.

During assembling, the connections between the windings and between the windings and the peripheral circuit can be realized by means of a printed circuit board, specifically, by the metallization grooves or holes or connections on the printed circuit board. The printed circuit board can be designed according to the specific configuration of the integrated magnetic device (i.e. the arrangement and the connections between the windings). Therefore, the manufacturing and assembling efficiency can be greatly improved.

By using the integrated magnetic device of the present disclosure, the total volume can be reduced by about 54%. Besides, the height of the integrated magnetic device can be reduced by about 20%, which means the height of the magnetic component will no longer be the bottleneck for the radio board and the height of the radio product may be reduced further and therefore the radio product can be designed smaller. The integrated structure also facilitates mass production and increases manufacturing efficiency.

In addition, the decoupling inductance of the integrated magnetic device of the present disclosure can be 6 μH +/−20% or even higher. Our 5G product usually can have 1350W as power consumption, which means the maximum current may arrive at 37.5A (36V input voltage). With the integrated magnetic device of the present disclosure, the DC bias performance of the fifth winding is always larger than 7.2 μH during 0A to 60A. Thus, the decoupling inductor portion of the integrated magnetic device of the present disclosure can perform well to satisfy the requirement in 5G product.

With the integrated magnetic device of the present disclosure, the common mode choke's inductance can reach 225 μH +/−45%. Also, frequency response performance of the common mode chokes of the integrated magnetic device can be improved such that the common mode inductance can reach 125 μH at a frequency of 1 MHz. Therefore, the integrated magnetic component is more robust than conventional common mode chokes.

Additionally, the integrated magnetic device of the present disclosure exhibits a good performance in terms of thermal issues. At the environment temperature of 30.4° C., DC current of 30A flows through the integrated magnetic device for a period of time, and the highest temperature of 161.7° C. appears in the area of the fifth winding w5, and the first magnetic base may reach 106.7° C. and the temperature of the second magnetic base is about 91.7° C. The temperature of the first and second magnetic core columns may reach 143.8° C. In the area of the side support plate of the integrated magnetic device, the temperature is about 102.4° C. All these measurements show that working temperature of the magnetic integrated device of the present disclosure is at an acceptable level.

Although the integrated magnetic device stated in the above is explained as an example for a radio product, it can be readily understood that the integrated magnetic device of the present disclosure can be used in all the applications where both lightening protection function and EMI/EMC filtering function are needed.

References in the present disclosure to “an embodiment”, “another embodiment” and so on, indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

It should be understood that, the term “and/or” includes any and all combinations of one or more of the associated listed terms.

The terminology used herein is for the purpose of describing particular embodiments only and is not intended to limit the present disclosure. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components, but do not preclude the presence or addition of one or more other features, elements, components and/or combinations thereof. The terms “connect”, “connects”, “connecting” and/or “connected” used herein cover the direct and/or indirect connection between two elements.

The present disclosure includes any novel feature or combination of features disclosed herein either explicitly or any generalization thereof. Various modifications and adaptations to the foregoing exemplary embodiments of this disclosure may become apparent to those skilled in the relevant arts in view of the foregoing description, when read in conjunction with the accompanying drawings. However, any and all modifications will still fall within the scope of the non-limiting and exemplary embodiments of this disclosure.

1. An integrated magnetic (IM) device, comprising:
a common magnetic core portion comprising a first magnetic base and a second magnetic base that is spaced in a first direction from the first magnetic base;
a first magnetic core column and a second magnetic core column, which extend between the first and second magnetic bases and spaced with each other along a second direction perpendicular to the first direction, the first magnetic core column and the second magnetic core column and the first and second magnetic bases together forming a closed magnetic path, and the first magnetic core column and the second magnetic core column having windings wound thereon so as to form one or more common mode chokes; and
a middle magnetic core portion extending between the first and second magnetic bases and located between the first magnetic core column and the second magnetic core column along the second direction, with an air gap being provided in an extension direction of the middle magnetic core portion which is made of high saturation magnetic material, and the middle magnetic core portion comprising a winding wound thereon so as to form a decoupling inductor.

2. The integrated magnetic device according to claim 1, wherein the middle magnetic core portion is in the form of a single column, with the air gap being formed between an end of the single column and an inner side of a magnetic base which the single column extends towards.

3. The integrated magnetic device according to claim 1, wherein the first magnetic core column and the second magnetic core column and the common magnetic core portion are made of the same magnetic material with high permeability.

4. The integrated magnetic device according to claim 3, wherein one or both of the first magnetic core column and the second magnetic core column are integrally formed with one or both of the first magnetic base and the second magnetic base of the common magnetic core portion.

5. The integrated magnetic device according to claim 3, wherein one or both of the first magnetic core column and the second magnetic core column are formed by two abutting halves protruding from one of the magnetic bases towards the other; and
wherein the halves of the first magnetic core column and the second magnetic core column are integrally formed with magnetic bases of the common magnetic core portion.

6. (canceled)

7. The integrated magnetic device according to claim 1, wherein a first winding and a third winding are provided on the first magnetic core column and arranged next to each other along the first direction, with the first winding being placed adjacent to the first magnetic base;
a second winding and a fourth winding are provided on the second magnetic core column and arranged next to each other along the first direction, with the second winding being placed adjacent to the first magnetic base;
a fifth winding is provided on the middle magnetic core portion; and
each winding has a first end and a second end which is located closer to the first magnetic base than the first end.

8. The integrated magnetic device according to claim 7, wherein the first winding, the second winding, the third winding and the fourth winding are wound and connected in such a manner that a first common mode choke is formed by the first winding and the third winding, and a second common mode choke is formed by the second winding and the fourth winding.

9. The integrated magnetic device according to claim 8, wherein:
the first winding, the second winding, the third winding, the fourth winding and the fifth winding each have coils wound in the same direction;
a second end of the fifth winding is connected to a second end of the first winding, a first end of the first winding is connected to a first end of the second winding;
a second end of the third winding is connected to a second end of the fourth winding; and
a second end of the second winding, a first end of the third winding, a first end of the fourth winding and a first end of the fifth winding are all led out as peripheral interfaces of the integrated magnetic device.

10. The integrated magnetic device according to claim 7, wherein the first winding, the second winding, the third winding and the fourth winding are wound and connected in such a manner that a first common mode choke is formed by the first winding and the second winding and a second common mode choke is formed by the third winding and the fourth winding.

11. The integrated magnetic device according to claim 10, wherein:
the first winding, the second winding, the third winding and the fourth winding each have coils wound in the same direction;
a second end of the fifth winding is connected to a second end of the first winding, a first end of the first winding is connected to a second end of the third winding;
a first end of the second winding is connected to a second end of the fourth winding; and
a second end of the second winding, a first end of the third winding, a first end of the fourth winding and a first end of the fifth winding are all led out as peripheral interfaces of the integrated magnetic device.

12. The integrated magnetic device according to claim 11, wherein the fifth winding has coils wound in the same direction as coils of the first winding, the second winding, the third winding and the fourth winding, such that magnetic flux produced by the fifth winding on the middle magnetic core portion and leakage flux generated by the first, second, third and fourth windings are superimposed with each other.

13. The integrated magnetic device according to claim 11, wherein the fifth winding has coils wound in an opposite direction to coils of the first winding, the second winding, the third winding and the fourth winding, such that magnetic flux produced by the fifth winding on the middle magnetic core portion and leakage flux generated by the first, second, third and fourth windings are canceled with each other.

14. The integrated magnetic device according to claim 3, wherein the magnetic material with high permeability comprises Mn—Zn soft ferrite material.

15. The integrated magnetic device according to claim 1, wherein:
the high saturation magnetic material comprises powder core;
the integrated magnetic device comprises a side support plate connecting the first and second magnetic bases along their longitudinal edges on the same side; and
the side support plate is made of epoxy material.

16. (canceled)

17. (canceled)

18. The integrated magnetic device according to claim 15, wherein the integrated magnetic device comprises a support frame arranged at a side opposite to the side where the side support plate is located, the support frame being configured for fixing pins led out from windings wound on the first and second magnetic core columns and the middle magnetic core portion; and
wherein the support frame is made of phenolic plastics.

19. (canceled)

20. A filter circuit, comprising:
a first transmission line;
a second transmission line; and
an integrated magnetic device, the integrated magnetic device having:
a common magnetic core portion comprising a first magnetic base and a second magnetic base that is spaced in a first direction from the first magnetic base;
a first magnetic core column and a second magnetic core column, which extend between the first and second magnetic bases and spaced with each other along a second direction perpendicular to the first direction, the first magnetic core column and the second magnetic core column and the first and second magnetic bases together forming a closed magnetic path, and the first magnetic core column and the second magnetic core column having wound thereon so as to form one or more common mode chokes; and
a middle magnetic core portion extending between the first and second magnetic bases and located between the first magnetic core column and the second magnetic core column along the second direction, with an air gap being provided in an extension direction of the middle magnetic core portion which is made of high saturation magnetic material, and the middle magnetic core portion comprising a winding wound thereon so as to form a decoupling inductor; and
each of the one or more common mode chokes comprising a winding connected in series in the first transmission line and a winding connected in series in the second transmission line, the decoupling inductor of the integrated magnetic device is connected in series in the second transmission line, with the winding of each common mode choke in the second transmission line being connected in series downstream of the decoupling inductor.

21. The integrated magnetic device according to claim 2, wherein a first winding and a third winding are provided on the first magnetic core column and arranged next to each other along the first direction, with the first winding being placed adjacent to the first magnetic base;
a second winding and a fourth winding are provided on the second magnetic core column and arranged next to each other along the first direction, with the second winding being placed adjacent to the first magnetic base;
a fifth winding is provided on the middle magnetic core portion; and
each winding has a first end which is located closer to the first magnetic base than the first end.

22. The integrated magnetic device according to claim 21, wherein the first winding, the second winding, the third winding and the fourth winding are wound and connected in such a manner that a first common mode choke is formed by the first winding and the third winding, and a second common mode choke is formed by the second winding and the fourth winding.

23. The integrated magnetic device according to claim 22, wherein:
the first winding, the second winding, the third winding, the fourth winding and the fifth winding each have coils wound in the same direction;
a second end of the fifth winding is connected to a second end of the first winding, a first end of the first winding is connected to a first end of the second winding;
a second end of the third winding is connected to a second end of the fourth winding and
a second end of the second winding, a first end of the third winding, a first end of the fourth winding and a first end of the fifth winding are all led out as peripheral interfaces of the integrated magnetic device.

24. The integrated magnetic device according to claim 21, wherein the first winding, the second winding, the third winding and the fourth winding are wound and connected in such a manner that a first common mode choke is formed by the first winding and the second winding and a second common mode choke is formed by the third winding and the fourth winding.
